(19) United States
(12) Patent Application Publication
(10) Pub. No.: US 2008/0011510 A1
(43) Pub. Date: Jan. 17, 2008

(54) Hybrid faceplate having reduced EMI emissions

(75) Inventors: Zheng Tang, Shanghai (CN); Liang Zheng, Shanghai (CN); Hongliang Jiang, Shanghai (CN)

Correspondence Address: SABIC - 08CT;SABIC Innovative Plastics - IP Legal, ONE PLASTICS AVENUE, PITTSFIELD, MA, 01201-3697, US

(73) Assignee: General Electric Company

(21) Appl. No.: 11/509,358

(22) Filed: Aug. 24, 2006

Related U.S. Application Data
(60) Provisional application No. 60/807,101, filed on Jul. 12, 2006.

(51) Int. Cl. H05K 9/00

(52) U.S. Cl. 174/350

(57) ABSTRACT

A hybrid plastic-metal faceplate having reduced EMI emissions for use with electric circuit card rack systems. The faceplate uses an electrically conductive thermoplastic front plate that is simpler to construct. The faceplate also includes a first metal element in electrically conducting contact with the front plate and a second metal element in electrically conducting contact with the front plate. The plastic-metal faceplates have an EMI shielding effectiveness of 20 dB or greater across the range of frequencies of 0 MHz to 1.0 GHz. The faceplate may be used in a variety of different applications, such as electric circuit card rack systems, to reduce EMI (electromagnetic interference) emissions from the electric circuit card system.

### CROSS REFERENCE TO RELATED APPLICATIONS

This application claims priority to U.S. Provisional Application No. 60/807,101, which was filed Jul. 12, 2006.

### FIELD OF INVENTION

The present invention relates to faceplates and, in particular, to hybrid faceplates for use with electric circuit card rack systems.

### BACKGROUND OF INVENTION

Many types of electrical equipment produce stray electromagnetic radiation, referred to as electromagnetic interference (EMI). EMI may occur, for example, from analog circuit components or from digital components. EMI emissions are undesirable since they can potentially interfere with the operation of nearby electrical equipment. In addition, regulations have been established for the maximum permissible EMI emissions from various types of electrical equipment, and these regulations must be taken into account when designing new equipment in which EMI might be a problem.

For some types of electronic equipment, such as those that use electric circuit cards (e.g. electric circuit rack card systems), EMI reduction is difficult because of the basic design of the equipment and the need to allow access to the equipment. Typically, electric circuit rack card systems include banks of circuit cards that include one or more pullout circuit cards. The circuit cards are often contained in the frame or housing of the rack card system. The housing is grounded and provides effective EMI shielding at the top, bottom, sides, and back of the rack card system, but there is little shielding at the front since the frame is generally left open to allow for the removal and replacement of the individual circuit cards. As a result, the front opening of each row or shelf in the housing acts as a slot or waveguide antenna for the electromagnetic radiation. Even though these openings are physically closed off by the channel unit faceplates when all of the channel units are fully inserted, they can be electrically open if the faceplates are constructed from a material that provides little resistance to electromagnetic radiation.

Several approaches have been developed for reducing EMI emissions in these rack card systems. For example, as described in U.S. Pat. Nos. 4,991,062 and 5,084,802, a resilient metal strip is fastened to the back of the circuit card faceplate and configured to contact the outwardly facing conductive areas of the grounded channel bank housing when the channel unit is inserted into the grounded channel bank housing. The resilient metal strip thus creates an electroconductive shunt across the shelf opening and reduces its effectiveness as a slot antenna. Other arrangements for reducing EMI emissions in telephone channel banks are described in U.S. Pat. No. 5,386,346, U.S. Pat. No. 5,491,613, and U.S. Pat. No. 5,463,532. However, while these prior art embodiments may be effective in reducing EMI emissions, they do not provide a substantially continuous conductive shell or Faraday shield across the shelf opening that eliminates all or essentially all EMI emissions. In particular, in all of the arrangements discussed above, an electrically open space, if not a physical space, transparent to electromagnetic radiation exists between the adjacent channel unit faceplates, through which some EMI can be emitted into the surrounding environment.

Another prior art embodiment, which attempts to remedy the deficiencies of the prior art, is U.S. Pat. No. 6,172,880, which provides a faceplate and a movable plate. The faceplate is adapted to mount to an electronic circuit card. The movable plate has a free edge and is movably coupled to the faceplate to move with respect to the faceplate between a retracted position, at which the free edge is substantially aligned with the faceplate, and an extended position at which the free edge extends past the faceplate. The extended position is used for reducing EMI emissions through openings between the faceplates of adjacent electronic circuit cards inserted in a housing and the retracted position enables the electronic circuit cards to be removed essentially without restriction from the circuit card housing. However, this prior art solution utilizes multiple parts, making these faceplates more susceptible to breaking. In addition, when in the retracted position, the EMI shielding is no longer in effect such that the added complexity of a movable faceplate provides no EMI shielding benefit.

In still another prior art embodiment, a faceplate is constructed from an aluminum extrusion “front plate”, beryllium-copper as a shielding strip, two die-casting end fixtures, two latch units, two hinge pins and screws. In this design, the beryllium-copper strip is used to shield up the gap between two conjunctive plates, while the aluminum plate is used to shield the front face. However, in this embodiment, beryllium-copper is an expensive material that increases the costs associated with these faceplates. And since electric circuit card rack systems can include significant numbers of faceplates in a single electric circuit card rack system, the use of a beryllium-copper strip can significantly increase the cost of these prior art systems.

Accordingly, it would be beneficial to provide an EMI shielding faceplate for use in electric circuit card rack systems that reduces or eliminates one or more problems associated with the prior art systems. In particular, it would be beneficial to provide an EMI shielding faceplate for use in electric circuit card rack systems that is less expensive than prior art systems. In addition, it would be beneficial to provide an EMI shielding faceplate for use in electric circuit card rack systems that is simpler than prior art systems.

### SUMMARY OF THE INVENTION

The present invention provides a new and useful faceplate for use with electric circuit card rack systems, such as telephone channel banks. The faceplate provides EMI shielding effectiveness using a hybrid plastic-metal construction that is simpler and/or less expensive to construct than prior art faceplates. The faceplate provides EMI shielding effectiveness using a hybrid plastic-metal construction. That eliminates several of the separate pieces used in prior art faceplates, thereby making the faceplates of the present invention simpler in their design and manufacture. In addition, the replacement of plastic reduces the costs associated with making the faceplates. Nevertheless, the faceplates of the present invention still provide an EMI shielding effectiveness of 20 dB or greater across the range of frequencies of 300 MHz to 1.6 GHz.

In one aspect, the present invention provides a hybrid faceplate for use in electric circuit card rack systems. The hybrid faceplate includes an electrically conductive thermoplastic front plate, a first metal element in electrically conducting contact with the front plate; and a second metal element in electrically conducting contact with the front plate and the first metal element, wherein the faceplate has an EMI shielding effectiveness of 20 dB or greater.

In another aspect, the present invention provides a method of making a faceplate for use in electric circuit card rack systems. The method includes the steps of molding a front plate using an electrically conductive thermoplastic composition, integrating a first metal element with the front plate such that the first metal element is in electrically conducting contact with the front plate, and integrating a second metal element with the front plate such that the second metal element is in electrically conducting contact with the front plate and the first metal element; wherein the faceplate has an EMI shielding effectiveness of 20 dB or greater

### BRIEF DESCRIPTION OF THE DRAWINGS

FIG. 1 is an exploded view of a hybrid plastic-metal faceplate according to one embodiment of the present invention.

FIG. 2 is a close-up view of a hybrid plastic-metal faceplate according to one embodiment of the present invention.

FIG. 3 is a side view of a metal finger used in one embodiment of a hybrid plastic-metal faceplate according to the present invention.

FIGS. 4a and 4b are a perspective view and a close-up view of a metal tab used in one embodiment of a hybrid plastic-metal faceplate according to the present invention.

### DETAILED DESCRIPTION OF THE INVENTION

The present invention is more particularly described in the following description and examples that are intended to be illustrative only since numerous modifications and variations therein will be apparent to those skilled in the art. As used in the specification and in the claims, the singular form “a,” “an,” and “the” may include plural referents unless the context clearly dictates otherwise. Also, as used in the specification and in the claims, the term “comprising” may include the embodiments “consisting of” and “consisting essentially of.” Furthermore, all ranges disclosed herein are inclusive of the endpoints and are independently combinable.

As used herein, approximating language may be applied to modify any quantitative representation that may vary without resulting in a change in the basic function to which it is related. Accordingly, a value modified by a term or terms, such as “about” and “substantially,” may not be limited to the precise value specified, in some cases. In at least some instances, the approximating language may correspond to the precision of an instrument for measuring the value.

The present invention provides a new and useful faceplate. The faceplate may be used in a variety of different applications, such as electric circuit card rack systems, to reduce EMI (electromagnetic interference) emissions from the electric circuit card system. The faceplate provides EMI shielding effectiveness using a hybrid plastic-metal construction. Since prior art systems generally include a metal (e.g. aluminum) front plate, a second metal (e.g. beryllium-copper) as a shielding strip, two die-casting end fixtures, two latch units, two hinge pins and screws, the prior art systems have a significant number of pieces and are constructed from materials that are expensive to form into a faceplate. However, since the present invention uses a hybrid plastic-metal construction, the present invention eliminates several of the separate pieces making the faceplates of the present invention simpler in their design and manufacture. In addition, the replacement of plastic reduces the costs associated with making the faceplates. Nevertheless, the faceplates of the present invention still provide an EMI shielding effectiveness of 20 dB or greater across the range of frequencies of 0 Hz to 1.0 GHz.

In one embodiment, the faceplates of the present invention include a front plate constructed from an electrically conductive thermoplastic composition, a first metal element in electrical contact with the front plate for enhancing EMI shielding, and a second metal element in electrical contact with the electrically conductive thermoplastic composition and the first metal element for further enhancing EMI shielding to shield any gap between two conjunctive faceplates. By using an electrically conductive thermoplastic composition for the front plate rather than a metal front plate, the front plate can be formed with die-casting end fixtures integrated into the front plate, thereby reducing the expense and number of process steps needed to form the front plate and, therefore, the faceplate.

Accordingly, in one aspect, the present invention utilizes a front plate constructed using an electrically conductive thermoplastic composition. By using a thermoplastic material, the front plate may be formed such that additional components of the front plate (e.g. the die-casting end fixtures) are integrated into the front plate in a single step when the front plate is formed.

In addition, since the electrically conductive thermoplastic composition includes electrically conducting materials, these electrically conducting materials cause the electrically conductive thermoplastic composition to provide some degree of EMI shielding as compared to thermoplastic compositions that do not have electrically conducting materials since thermoplastics generally have little or no EMI shielding effectiveness. But, adding electrically conducting materials to the thermoplastic composition results in an electrically conductive thermoplastic composition that will have some EMI shielding effectiveness.

Lastly, by using an electrically conductive thermoplastic composition, one or more metal elements may be integrated with the electrically conductive thermoplastic composition and they may be in electrically conducting contact with each other and/or the front plate due to the electrically conducting materials contained within the electrically conductive thermoplastic composition.

Accordingly, by using an electrically conductive thermoplastic composition as the front plate, a first metal element can be integrated with the front plate in a manner that causes the first metal element to be in electrically conducting contact with the front plate thereby permitting the first metal element to enhance the EMI shielding of the faceplate. The first metal element, due to the structure of the front plate and/or the manner in which it is integrated with the front plate, is in electrically conducting contact with the front plate through contact of the first metal element with one or more electrically conducting materials (e.g. metal fibers) in the electrically conductive thermoplastic composition.

In addition, a second metal element can be integrated with the front plate in a manner that causes the second metal element to be in electrically conducting contact with the front plate and with the first metal element. In one embodiment, the first metal element and the second metal element are in direct contact with each other and with the front plate. In another embodiment, the first metal element and the second metal element are in direct contact with the front plate, but are not in direct contact with each other.

The electrically conductive thermoplastic compositions used in the present invention include a thermoplastic resin and an electrically conducting material. The thermoplastic resin in the electrically conductive thermoplastic composition may be selected from a wide variety of thermoplastic resins or blends of thermoplastic resins. Examples of thermoplastic resins that may be used in the present invention include, but are not limited to, polyacetals, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyoxadiazoles, polybenzothiazinophenothiazines, polybenzothiazoles, polypyrazinoquinoxalines, polypyromellitimides, polyquinoxalines, polybenzimidazoles, polyoxindoles, polyoxoisoindolines, polydioxoisoindolines, polytriazines, polypyridazines, polypiperazines, polypyridines, polypiperidines, polytriazoles, polypyrazoles, polypyrrolidines, polycarboranes, polyoxabicyclononanes, polydibenzofurans, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, or the like, or a combination comprising at least one of the foregoing organic polymers.

Specific non-limiting examples of blends of thermoplastic resins include acrylonitrile-butadiene-styrene/nylon, polycarbonate/acrylonitrile-butadiene-styrene, polyphenylene ether/polystyrene, polyphenylene ether/polyamide, polycarbonate/polyester, polyphenylene ether/polyolefin, and combinations including at least one of the foregoing blends of thermoplastic resins.

In addition to the thermoplastic resin, the electrically conductive thermoplastic composition also includes an electrically conducting material. In one embodiment, the electrically conducting material includes a plurality of electrically conducting fibers used to impart electrically conductive characteristics to the electrically conductive thermoplastic composition. In one embodiment, the electrically conducting fibers are selected from metal fibers. Examples of metal fibers that may be used in the present invention include, but are not limited to, stainless steel fibers, aluminum fibers, copper fibers, and the like. In another embodiment, the electrically conducting fibers are selected from electrically conductive carbon fibers.

Examples of electrically conductive thermoplastic compositions that may be used in the present invention include, but are not limited to, FARADEX® electrically conductive resins available from General Electric Company (Pittsfield, Mass.). FARADEX® electrically conductive resins are composed from a base resin, such as polycarbonate, acrylonitrile-butadiene-styrene, polypropylene, or a blend thereof and a plurality of electrically conductive fibers, such as stainless steel fibers.

The first and second metal elements used in the faceplates of the present invention may be constructed from any metal capable of enhancing the EMI shielding effectiveness of the faceplates of the present invention. In one embodiment, the first metal element is designed to enhance the EMI shielding effectiveness of the faceplate itself while the second metal element is designed to enhance the EMI shielding effectiveness of the faceplate by providing EMI shielding in the gaps between conjunctive faceplates (and, therefore, between conjunctive electric circuit cards).

Accordingly, in one embodiment of the present invention, the faceplate includes a first metal element. The first metal element may be integrated with the front plate by attaching the first metal element to a surface of the front plate or by embedding, either partially or completely, the first metal element in the front plate. Whether the first metal element is attached to a surface of the front plate or embedded therein, the first metal element is integrated with the front plate such that the first metal element is in electrically conducting contact with the electrically conducting materials in the front plate.

The first metal element may be constructed from any metal capable of enhancing the EMI shielding effectiveness of the faceplate. Examples of metals that may be used to form the first metal element include, but are not limited to, stainless steel, aluminum, copper, or a combination thereof. The shape of the first metal element may be any shape that permits the first metal element to enhance the EMI shielding effectiveness of the faceplate. Accordingly, the first metal element may be in the form of a plate, rod, mesh or the like. In one embodiment, the first metal element is in the form of a metal mesh. The use of the metal mesh provides a metal element with some degree of flexibility to help reduce any possible shrinkage between the front plate and the first metal element and/or to help reduce any warpage of the faceplate.

The faceplates of the present invention also include a second metal element designed to enhance the EMI shielding effectiveness of the faceplate by providing EMI shielding between adjacent faceplates/circuit cards. As with the first metal element, the second metal element may be constructed from any metal capable of enhancing the EMI shielding effectiveness of the faceplate and may take any shape that permits the second metal element to enhance the EMI shielding effectiveness of the faceplate. As such, metals that may be used to form the second metal element include, but are not limited to, stainless steel, aluminum, copper, or a combination thereof. The shape of the second metal element may include a sheet of metal having a plurality of fingers that extend slightly away from the front plate in a curved or arched manner such that the metal fingers extend at least partially across the gap between adjacent faceplates/circuit cards, thereby permitting the second metal element to enhance the overall EMI shielding effectiveness of the faceplate.

As with the first metal element, the second metal element may be integrated with the front plate by attaching the second metal element to a surface of the front plate or by embedding, either partially or completely, the second metal element in the front plate. In one embodiment, the second metal element is attached such that it is in direct contact with the first metal element. Whether the second metal element is attached to a surface of the front plate or embedded therein, and/or whether the second metal element is in direct contact with the first metal element or not, the second metal element is integrated with the front plate such that the second metal element is in electrically conducting contact with the electrically conducting materials in the front plate. In alternative embodiments, the second metal element includes metal tabs at one or both ends of the second metal element to achieve even better grounding of the faceplate.

The faceplates of the present invention, since they are constructed from a hybrid plastic-metal construction, may be manufactured using any method capable of forming a hybrid plastic-metal article. In one embodiment, the faceplate is formed using an injection-molded process wherein the front plate is formed. The first and second metal elements are then attached to the front plate in an electrically conductive manner, such as, in one embodiment, through the use of one or more hot melt bosses that enable contact of the electrically conducting materials in the front plate with the first and second metal elements. In another embodiment, a compression-molding step may be used to compress a metal element into the front plate. Nevertheless, by using an injection-molding process to form the front plate, as previously discussed, the two die-casting end fixtures can be formed with front plate, thereby reducing the number of steps needed to form the front plate and, therefore, the faceplate.

In another embodiment, the faceplate is constructed by insert-molding the first metal element, the second metal element, or both in the front plate using an insert-molding process. In addition, as with an injection-molding process, using an insert-molding process enables the two die-casting end fixtures to be formed with front plate, thereby reducing the number of steps needed to form the front plate and, therefore, the faceplate.

The foregoing and other features of the present invention will be more readily apparent from the following detailed description and drawings of the illustrative embodiments of the invention wherein like reference numbers refer to similar elements.

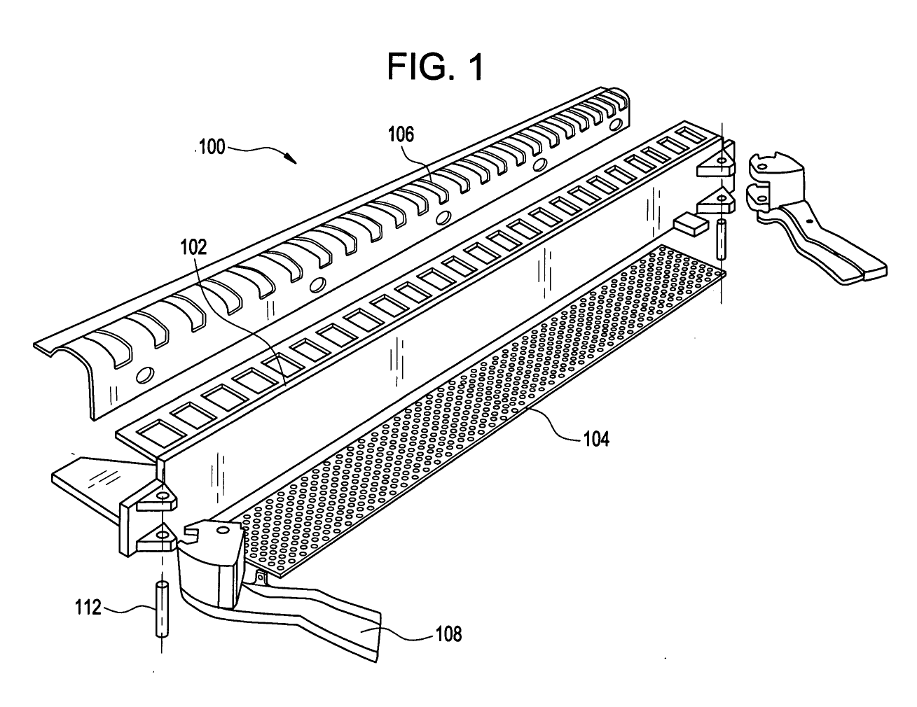

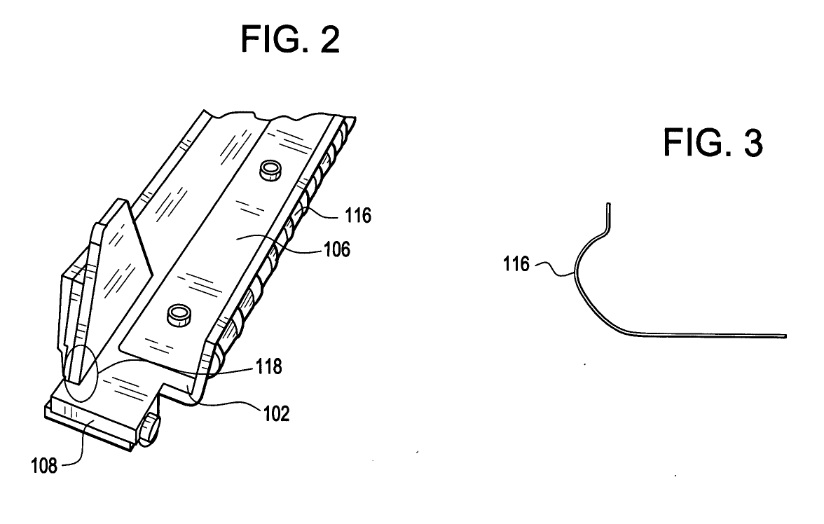

Referring to the drawings, FIGS. 1 and 2 provide a faceplate according to one embodiment of the present invention. As may better be seen in FIG. 1, the faceplate 100 includes a front plate 102, a first metal element 104 and a second metal element 106. Two latches 108 are connected at opposite ends of the front plate 102 at die-casting end fixtures 110 on the front plate 102 through the use of two hinge pins 112, one to connect each latch 108 to the faceplate 100 at each die-casting end fixture 110.

In this embodiment, the front plate 102 is constructed from an electrically conductive thermoplastic composition, the first metal element 104 is in the form of a metal mesh, and the second metal element 106 is in the form of a metal plate having a plurality of metal fingers 116. As may be seen in FIG. 3, the metal fingers 116 are curved to enable each finger 116 to extend across any gap between adjacent faceplates 100 when multiple faceplates are utilized in an electric card system having more than one circuit card.

As can be seen in FIG. 2, in construction, the first metal element 104 is partially embedded in the front plate 102. By partially embedding the first metal element 104 in the front plate 102, electrical contact between the first metal element 104 and the electrically conductive material in the front plate 104 can be achieved. Electrical contact between the second metal element 106 and the front plate 102 is achieved through the use of one or more hot melt bosses 118.

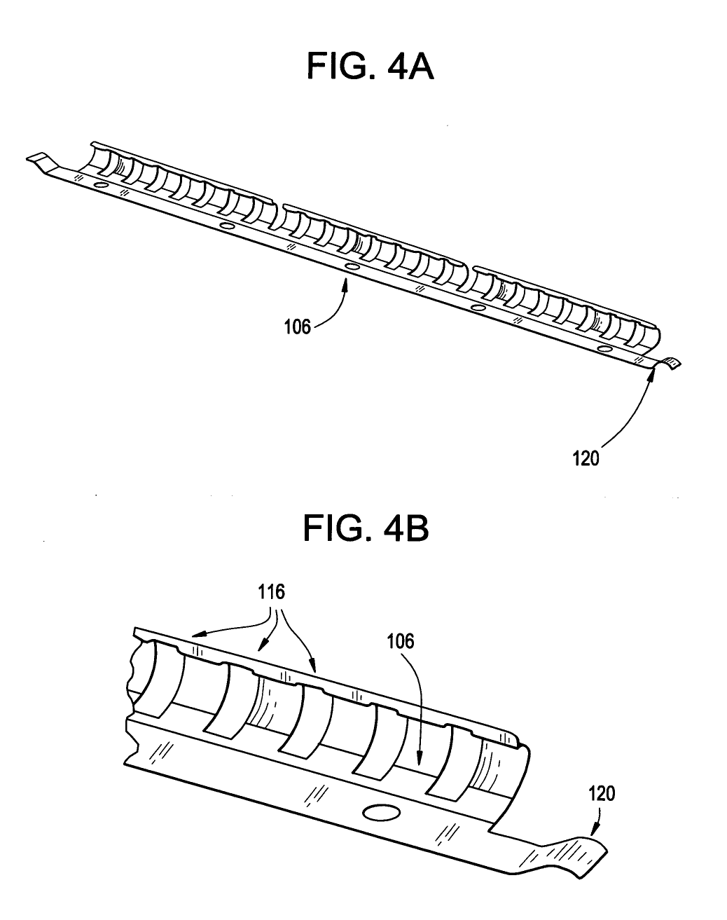

In an alternative embodiment, as shown in FIGS. 4a and 4b, the second metal element 106 can include metal tabs 120 located at each end of the second metal element 106 fro providing better grounding of the faceplate.

Accordingly, as may be seen, the faceplates of the present invention provide an improved hybrid-metal faceplate that may be used in any system utilizing electric circuit cards. The hybrid-metal faceplates are simpler in construction yet provide an EMI shielding effectiveness of 20 dB or greater across the range of frequencies of 0 Hz to 1.0 GHz.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A faceplate comprising:
an electrically conductive thermoplastic front plate;
a first metal element in electrically conducting contact with the front plate; and
a second metal element in electrically conducting contact with the front plate and the first metal element;
wherein the faceplate has an EMI shielding effectiveness of 20 dB or greater.

2. The faceplate of claim 1, wherein the first metal element is in a form of a metal mesh.

3. The faceplate of claim 1, wherein the second metal element is in a form of a sheet metal.

4. The faceplate of claim 1, wherein the electrically conductive thermoplastic front plate includes a thermoplastic resin selected from polyacetals, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyoxadiazoles, polybenzothiazinophenothiazines, polybenzothiazoles, polypyrazinoquinoxalines, polypyromellitimides, polyquinoxalines, polybenzimidazoles, polyoxindoles, polyoxoisoindolines, polydioxoisoindolines, polytriazines, polypyridazines, polypiperazines, polypyridines, polypiperidines, polytriazoles, polypyrazoles, polypyrrolidines, polycarboranes, polyoxabicyclononanes, polydibenzofurans, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, or the like, or a combination including at least one of the foregoing organic polymers.

5. The faceplate of claim 1, wherein the electrically conductive thermoplastic front plate includes an electrically conductive material selected from stainless steel fibers, aluminum fibers, copper fibers, electrically conductive carbon fibers, or a combination at least one of the foregoing.

6. The faceplate of claim 1, wherein the electrically conductive thermoplastic front plate comprises a thermoplastic resin selected from polycarbonate, acrylonitrile-butadiene-styrene, polypropylene, or a blend thereof and an electrically conductive material comprising stainless steel fibers.

7. The faceplate of claim 1, wherein the second metal element includes a tab on at least one end of the second metal element.

8. A method of forming a faceplate comprising:
molding a front plate using an electrically conductive thermoplastic composition;
integrating a first metal element with the front plate such that the first metal element is in electrically conducting contact with the front plate; and
integrating a second metal element with the front plate such that the second metal element is in electrically conducting contact with the front plate and the first metal element;
wherein the faceplate has an EMI shielding effectiveness of 20 dB or greater.

9. The method of claim 8, wherein the first metal element is in a form of a metal mesh.

10. The method of claim 8, wherein the second metal element is in a form of a sheet metal.

11. The method of claim 8, wherein the electrically conductive thermoplastic front plate includes a thermoplastic resin selected from polyacetals, polyacrylics, polycarbonates, polystyrenes, polyesters, polyamides, polyamideimides, polyarylates, polyarylsulfones, polyethersulfones, polyphenylene sulfides, polyvinyl chlorides, polysulfones, polyimides, polyetherimides, polytetrafluoroethylenes, polyetherketones, polyether etherketones, polyether ketone ketones, polybenzoxazoles, polyoxadiazoles, polybenzothiazinophenothiazines, polybenzothiazoles, polypyrazinoquinoxalines, polypyromellitimides, polyquinoxalines, polybenzimidazoles, polyoxindoles, polyoxoisoindolines, polydioxoisoindolines, polytriazines, polypyridazines, polypiperazines, polypyridines, polypiperidines, polytriazoles, polypyrazoles, polypyrrolidines, polycarboranes, polyoxabicyclononanes, polydibenzofurans, polyphthalides, polyacetals, polyanhydrides, polyvinyl ethers, polyvinyl thioethers, polyvinyl alcohols, polyvinyl ketones, polyvinyl halides, polyvinyl nitriles, polyvinyl esters, polysulfonates, polysulfides, polythioesters, polysulfones, polysulfonamides, polyureas, polyphosphazenes, polysilazanes, or the like, or a combination including at least one of the foregoing organic polymers.

12. The method of claim 8, wherein the electrically conductive thermoplastic front plate includes an electrically conductive material selected from stainless steel fibers, aluminum fibers, copper fibers, electrically conductive carbon fibers, or a combination at least one of the foregoing.

13. The method of claim 8, wherein the electrically conductive thermoplastic front plate comprises a thermoplastic resin selected from polycarbonate, acrylonitrile-butadiene-styrene, polypropylene, or a blend thereof and an electrically conductive material comprising stainless steel fibers.

14. The method of claim 8, wherein the electrically conductive thermoplastic front plate is formed using an injection molding process.

15. The method of claim 8, wherein the electrically conductive thermoplastic front plate is formed using an insert molding process wherein the first metal element is embedded in the electrically conductive thermoplastic front plate.
